(19) United States
(12) Patent Application Publication
(10) Pub. No.: US 2025/0221061 A1
(43) Pub. Date: Jul. 3, 2025

(54) Silicon Avalanche Diode Detector

(71) Applicants: Sushant Sonde, Westmont, IL (US); Ronald Lipton, Long Beach, IN (US)

(72) Inventors: Sushant Sonde, Westmont, IL (US); Ronald Lipton, Long Beach, IN (US)

(21) Appl. No.: 18/942,675

(22) Filed: Nov. 9, 2024

Related U.S. Application Data
(60) Provisional application No. 63/547,881, filed on Nov. 9, 2023.

(51) Int. Cl. H10F 30/225

(52) U.S. Cl. CPC H10F 30/225

(57) ABSTRACT

A patterned collection electrode includes a dielectric layer isolating the contact metal edge from the silicon bulk. The dielectric/metal contact pad structure can be designed as a field plate with the metal edge carried past the edge of the n++-implant. This drives the high fields away from the n++ implant edge. The horizontal cut now shows that the peak field has moved away from the trench and the field within the gain layer is more uniform. The highest field is contained in the dielectric layer, which has a high breakdown voltage—thus improving device operational reliability. The device can be fabricated as a single diode detector element or can be fabricated in a strip of diode detector elements or an array of pixelated focal plane detectors.

This application claims the benefit of U.S. Provisional application Ser. No. 63/547,881 filed Nov. 9, 2023.

### STATEMENT REGARDING FEDERALLY SPONSORED RESEARCH OR DEVELOPMENT

This invention was made with government support under US Government contract: DE-SC0023592 awarded by Department of Energy. The government has certain rights in the invention.

### BACKGROUND

Conventional silicon avalanche diode detector device structure with trench isolation junction termination is prone to non-uniform device performance due to non-uniform electric field distribution and resulting variations in avalanche gain thus affecting the performance of the device (silicon avalanche diode).

FIG. 1(a) illustrates a conventional avalanche diode detector individual pixel 8a, including a metal contact pad 10. Above the metal contact pad 10 is a 500 μm thick p++ low resistivity silicon wafer 12. Above the silicon wafer 12 is a drift region layer 13, an undoped silicon layer. Above the drift region layer 13 is a p+ Boron doped silicon layer 14. Above the p+ layer 14 is an undoped silicon layer 14a. Above the undoped silicon layer 14a is an n+ phosphorus doped silicon layer 15. The p+ doped silicon layer 14, the undoped silicon layer 14a and the n+ doped silicon layer 15 together constitute a buried gain layer 16. Above the n+ doped silicon layer 15 is an undoped silicon layer 15a. Above the undoped silicon layer 15a is a resistive layer 17a, an n++ phosphorous doped silicon layer. Above the resistive layer 17a is a metal contact pad 19a. Pixel 8a includes etched trenches 18, or deep trench array terminations.

FIG. 2(a) shows the electric field profile for a conventional buried gain layer diode detector (uniform top n implant) as depicted in FIG. 1(a). FIG. 2b) is a horizontal cut through the gain region in FIG. 1(a).

US Patent Applications 2022/0050184 and US 2010/0133636 also describe avalanche diode detectors and are herein incorporated by reference to the extent they are not contrary to the presently described embodiments.

### SUMMARY

This invention disclosure describes a new design for a silicon avalanche diode detector.

A patterned collection electrode includes a dielectric layer isolating the contact metal edge from the silicon bulk (FIG. 1(b)). The dielectric/metal contact pad structure can be designed as a field plate with the metal edge carried past the edge of the n++-implant. This drives the high fields away from the n++ implant edge (FIG. 2(c)). The horizontal cut now shows that the peak field has moved away from the trench and the field within the gain layer is more uniform (FIG. 2(d)). The highest field is contained in the dielectric layer, which has a high breakdown voltage—thus improving device operational reliability.

The uniformity can be further improved by adjusting the boron/phosphorus ratio in the gain layer as explained below.

The variation of the boron (14)/phosphorus (15) ratio in the device avalanche gain region does not have a substantial effect on the maximum avalanche gain or device operating voltage, but it does have a significant effect on the electric field in the top region of the device. In the proposed PCE design lowering the boron/phosphorus ratio improves both the top electric field and the uniformity of the field in the gain region (FIG. 3(c), 3(d)). This, in turn, improves the gain uniformity in the device.

The proposed device can be fabricated as a single diode detector element or can be fabricated in a strip of diode detector elements or an array of pixelated focal plane detectors.

Numerous other advantages and features of the present invention will become readily apparent from the following detailed description of the invention and the embodiments thereof, and from the accompanying drawings.

### BRIEF DESCRIPTION OF THE DRAWINGS

FIG. 1(a) is a schematic sectional view of an Individual pixel design in a conventional buried gain detector.

FIG. 1(b) is a schematic sectional view of an Individual pixel design in a pattered collection electrode buried gain layer detector according to one embodiment of the invention.

FIG. 2(a) is an electric field profile for a conventional buried gain layer diode detector (uniform top n implant) as depicted in FIG. 1(a).

FIG. 2b) is a horizontal cut through the gain region in FIG. 1(a) along line 1-1 from FIG. 2(a).

FIG. 2(c) is an electric field profile for a device with a patterned electrode configuration, as depicted in FIG. 1(b).

FIG. 2(d) is a horizontal cut for a device with a patterned electrode configuration as depicted in FIG. 1(b) along line 2-2 from FIG. 2(c).

FIG. 3(a) is an electric field profile through the gain layer for boron/phosphorus ratios of 1.2.

FIG. 3(b) is a horizontal cut through the gain layer for boron/phosphorus ratios of 1.2 along line 3-3 from FIG. 3(a).

FIG. 3(c) is an electric field profile through the gain layer for boron/phosphorus ratios of 0.8.

FIG. 3(d) is a horizontal cut through the gain layer for boron/phosphorus ratios of 0.8 along line 3-3 from FIG. 3(c).

### DESCRIPTION

While this invention is susceptible of embodiment in many different forms, there are shown in the drawings, and will be described herein in detail, specific embodiments thereof with the understanding that the present disclosure is to be considered as an exemplification of the principles of the invention and is not intended to limit the invention to the specific embodiments illustrated.

This application incorporates by reference U.S. Provisional application Ser. No. 63/547,881 filed Nov. 9, 2023 in its entirety.

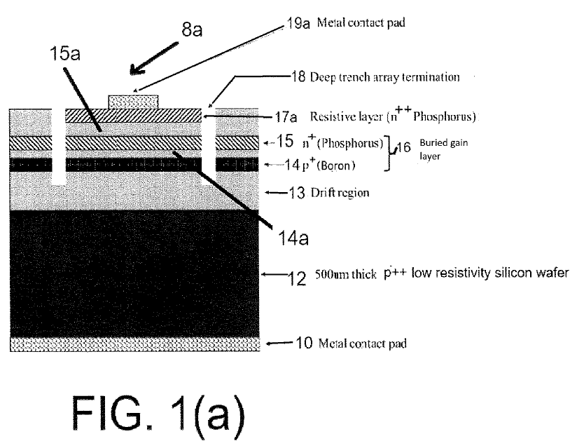

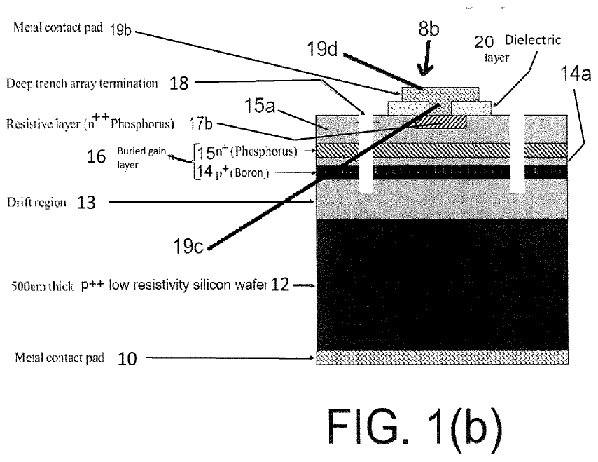

FIG. 1(b) illustrates an individual pixel design in a patterned collection electrode, buried gain layer diode detector. The patterned collection electrode design allows for stretching the metal contact pad beyond the resistive layer boundary with the help of a dielectric layer underneath.

FIG. 1(b) illustrates an individual pixel 8b, including a metal contact pad 10. Above the metal contact layer 10 is a p++ low resistivity silicon wafer 12, such as being 500 μm thick. Above the silicon wafer 12 is a drift region layer 13, such as an undoped silicon layer. Above the drift region layer 13 is a p+ doped silicon layer 14, such as by Boron. Above the p+ layer 14 is an undoped silicon layer 14a. Above the undoped silicon layer 14a is an n+ doped silicon layer 15, such as by phosphorus. The p+ doped silicon layer 14, the undoped silicon layer 14a and the n+ doped silicon layer 15 together constitute a buried gain layer 16. Above the n+ doped silicon layer 15 is an undoped silicon layer 15a. Above the undoped silicon layer 15a is a resistive layer 17b, such as an n++ doped silicon layer, such as by Phosphorous. Above the resistive layer 17b is a dielectric layer 20, such as a common oxide, for example SiO₂, Al₂O₃, HfO₂. Above and through the dielectric layer 20 is metal contact pad 19b. The metal contact pad 19b has a substantially T-shaped cross section and the central stem 19c of the pad 19b penetrates through the dielectric layer 20 to make contact with the resistive layer 17b. A top portion 19d of the metal contact pad is substantially greater in horizontal dimension than the resistive layer 17b and the dielectric layer 20 is substantially greater in horizontal dimension than the top portion 19d of the metal contact pad. Pixel 8b includes etched trenches 18, or deep trench array terminations.

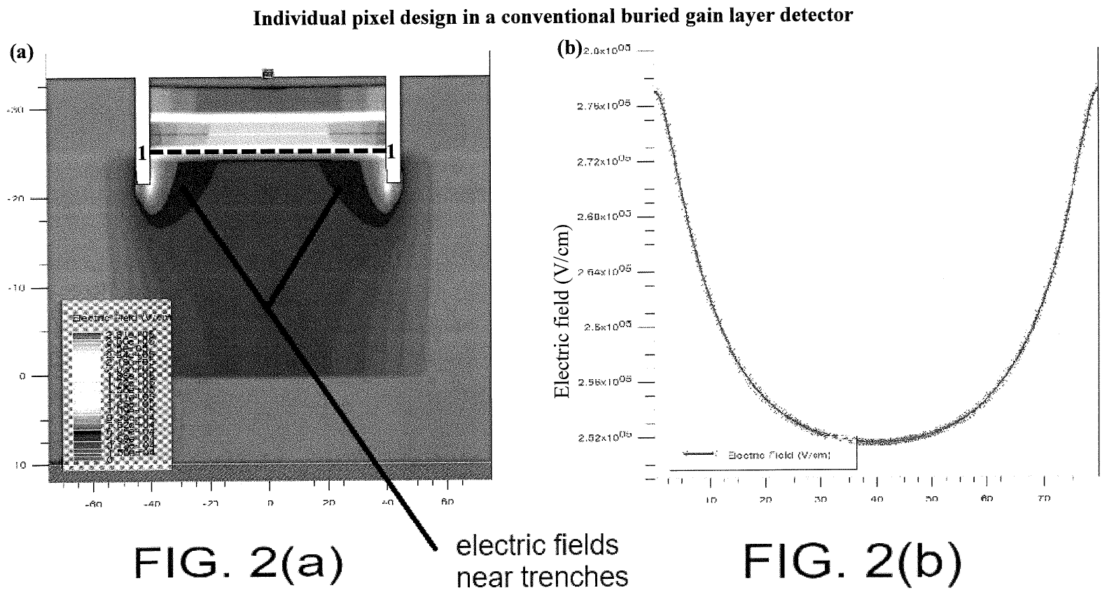

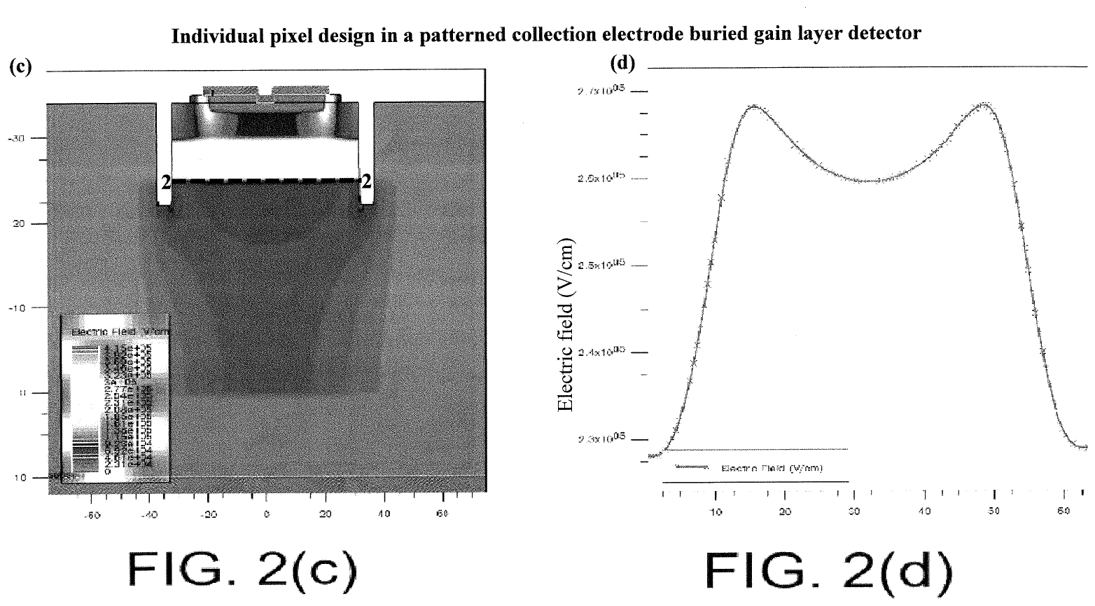

FIG. 2(c) is an electric field profile and FIG. 2(d) is a horizontal cut for a device with a patterned electrode configuration (as depicted in FIG. 1(b)) showing reduced electric fields near the trench and increased uniformity of the gain layer. Note the field concentration in the top dielectric layer near the metal contact pad edge.

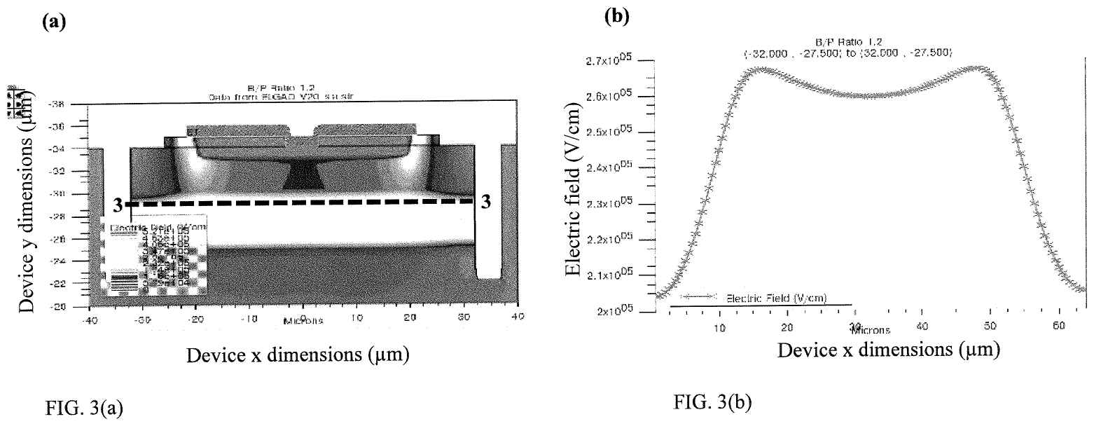

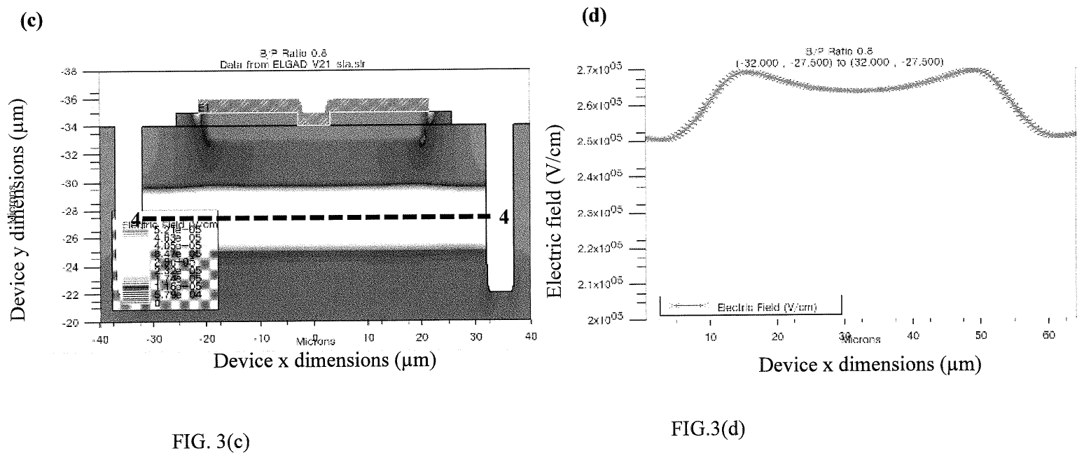

FIG. 3(a) is an electric field profile and FIG. 3(b) is a horizontal cut along line 3-3 of FIG. 3(a), for a device with a patterned electrode configuration (as depicted in FIG. 1(b) for boron/phosphorus ratios of 1.2.

FIG. 3(c) is an electric field profile and FIG. 3(d) is a horizontal cut along line 4-4 of FIG. 3(c), for a device with a patterned electrode configuration (as depicted in FIG. 1(b) for boron/phosphorus ratios of 0.8. Note the lower electric field in the top region of the device in (c) and better gain uniformity in (d) for the device with B/P ratio of 0.8.

From the foregoing, it will be observed that numerous variations and modifications may be effectuated without departing from the spirit and scope of the invention. It is to be understood that no limitation with respect to the specific apparatus illustrated herein is intended or should be inferred.

The invention claimed is:

1. A silicon avalanche diode detector, comprising:
a metal contact pad;
a low resistivity silicon wafer on the metal contact pad;
a first undoped silicon layer on the low resistivity silicon layer;
a p+ doped silicon layer on the first undoped silicon layer;
a second undoped silicon layer on the p+ doped silicon layer;
a n+ doped silicon layer on the second undoped silicon layer;
a third undoped silicon layer on the n+ doped silicon layer;
a resistive layer on the third undoped silicon layer;
a dielectric layer on the resistive layer;
a metal contact having a conductive portion in contact with the resistive layer and penetrating the dielectric layer, and a contact portion continuous with the conductive portion and on the dielectric layer.

2. A patterned collection electrode comprising:
plural silicon layers;
a contact having a contact metal edge and a stem;
a dielectric layer between the contact metal edge and the silicon layers, isolating the contact metal edge from the silicon layers;
a resistive layer comprising an n++ layer on the silicon layers;
the stem in contact with the dielectric layer;
the contact and dielectric layer is configured as a field plate with the metal edge carried past the edge of the resistive layer, to drive high fields away from an edge of the n++ layer.

3. The patterned collection electrode according to claim 2, wherein the p+ doped silicon layer is doped with boron and the n+ layer is doped with phosphorous, and the boron/phosphorus ratio is between 0.8 and 1.2.

4. The patterned collection electrode according to claim 3, wherein the boron/phosphorus ratio is 0.8.

5. The patterned collection electrode according to claim 3, wherein the boron/phosphorus ratio is 1.2.
